(19) United States
(12) Patent Application Publication
(10) Pub. No.: US 2006/0131711 A1
(43) Pub. Date: Jun. 22, 2006

(54) Package for semiconductor device

(76) Inventor: Yoshihiko Ino, Miyazaki (JP)

Correspondence Address: RABIN & BERDO, P.C.;Suite 500, 1101 14th Street, Washington, DC, 20005, US

(21) Appl. No.: 11/222,806

(22) Filed: Sep. 12, 2005

(30) Foreign Application Priority Data
Dec. 22, 2004 (JP) 2004-371102

(51) Int. Cl. H01L 23/02

(52) U.S. Cl. 257/678

(57) ABSTRACT

A lid for sealing a ceramic container receiving a semiconductor device such as an acceleration sensor is provided. The lid has an electrodeposition coating layer having a thickness of approximately 10 μm, which is formed by plating the outer surface of the 42 alloy plate having a thickness of approximately 100 μm with chrome and by forming a black color compound at the chrome plating layer. The lid is fixed to the upper end of a sidewall part of the ceramic container by means of a thermosetting resin. The thickness of the thermosetting resin after thermosetting is adjusted to be approximately 20 to 30 μm. The conventional ceramic lid needs 200 μm or more in thickness in view of strength, and has difficulty in laser processing. The lid of the present invention allows decreasing the thickness by half, and facilitating the imprint by laser.

### BACKGROUND OF THE INVENTION

1. Field of the Invention

The present invention relates to a package for a semiconductor device, and more particularly to the structure of a lid of a package for an acceleration sensor formed by a semiconductor.

2. Description of the Related Art

FIGS. 2A and 2B are views showing the structure of a conventional acceleration sensor. Specifically, FIG. 2A is a perspective view of a sensor body, and FIG. 2B is a sectional view of a package having the sensor body incorporated therein.

As shown in FIG. 2A, the sensor body 10 includes a fixing part 11 for fixing the sensor body to the package, a weight part 13 supported by four beams 12 extending from the fixing part 11 such that the weight part 13 is displaced due to acceleration, and piezo resistance elements 14 respectively placed at surfaces of the beams 12. The fixing part 11, the beams 12, and the weight part 13 are integrally shaped and made of silicon.

As shown in FIG. 2B, the package having the sensor body incorporated therein is formed by receiving the sensor body 10 in a ceramic container 20 and covering the ceramic container 20 with a ceramic lid 30.

The ceramic container 20 includes a bottom part 21 and a sidewall part 22. The sensor body 10 is fixed to the bottom part of the ceramic container 20. At the upper side of the sidewall part 22, a step part 22a is formed. A metal terminal 23 penetrates through the sidewall part 22 so as to extend from the step part 22a to the outside of the bottom part 21. The piezo resistance elements 14 placed at the surface of the sensor body 10 is connected to the metal terminal 23 via metal wires 24. The ceramic lid 30 is fixed to the sidewall part 22 of the ceramic container 20 by means of an adhesive agent. Noted that the weight part 13 of the sensor body 10 is spaced apart from the ceramic container 20 and the ceramic lid 30 such that the weight part 13 does not come into contact with the ceramic container 20 and the ceramic lid 30 even though the weight part 13 is displaced due to acceleration.

The acceleration sensor is mounted on an apparatus by means of the metal terminal 23 disposed at the rear side of the package. When acceleration is applied, the weight part 13 of the sensor body 10 is displaced, and then the four beams 12 are bent. As a result, resistance values of the piezo resistance elements 14 placed at the surfaces of the beams 12 are changed according to bending amounts of the respective beams 12. Accordingly, a three-dimensional direction and a magnitude of the acceleration are calculated based on the resistance values of the piezo resistance elements 14.

Japanese Patent Kokai No. 5-251577 discloses a method of manufacturing a ceramic package that has a capability of electromagnetic shield by metallizing a ceramic lid and by sealing the metallized ceramic lid and a base substrate with a conductive sealer. Japanese Patent Kokai No. 8-17951 discloses a semiconductor device having excellent printing and heat radiating characteristics by bonding a light color metallic plate coated with a dark color paint on the surface of a package and by burning away the paint with laser beams for printing.

Since the ceramic lid 30 is used to cover the ceramic container 20, the above-described acceleration sensors have the following problems:

(1) If the thickness of a ceramic plate is less than 0.2 mm, the ceramic plate may warp or crack. For this reason, it is difficult to provide a thinner ceramic plate, and making it difficult to reduce the overall thickness of the package. Furthermore, the acceleration sensors are more and more installed in mobile phones etc. having a function of a global position system (GPS). This leads to a demand for further miniaturization of the package.

(2) Printing on the package using laser beams is superior to printing on the package using ink in view of processing speed and simplified processing. However, printing on the ceramic with the laser beams requires high energy. Consequently, the provision of a special high-power laser oscillator is required, and a conventional manufacturing unit cannot be used.

### SUMMARY OF THE INVENTION

An object of the present invention is to provide a thinner package for a semiconductor device and excellent printing properties that are readily available.

According to the present invention, there is provided a package for a semiconductor device including a ceramic container having an internal space for receiving the semiconductor device, and a lid attached to an upper end of a sidewall part of the ceramic container for sealing the internal space of the ceramic container. The lid is formed by a black color electrodeposition coating layer applied either on the outer surface or the inner and outer surfaces of a stainless steel plate or a 42 alloy plate, or by applying copper coating layers on the inner and outer surfaces of a stainless steel plate and by black-finishing the copper coating layers by means of oxidization, or by a heat-resistant polyimide tape or a glass epoxy plate.

The lid is formed by a metal plate such as stainless steel or 42 alloy, a heat-resistant polyimide tape, or a glass epoxy plate. Accordingly, the lid is thinner and stronger than a ceramic lid formed by a ceramic plate. Furthermore, the outer surface of the metal plate is black-finished, and therefore, it is possible to easily imprint characters without using a high-power laser beam.

A thermosetting resin may be used to attach the lid to the ceramic container. Alternatively, the lid may be attached to the ceramic container by coating a thermoplastic resin on an entire surface of an inner side of the lid and by pressing the lid to the ceramic container while heating the thermoplastic resin.

### BRIEF DESCRIPTION OF THE DRAWINGS

FIG. 1 is a sectional view showing an acceleration sensor according to a first embodiment of the present invention;

FIGS. 2A and 2B are a perspective view and a sectional view, respectively, showing the structure of a conventional acceleration sensor;

FIG. 3 is a sectional view showing an acceleration sensor according to a second embodiment of the present invention;

FIG. 4 is a sectional view showing an acceleration sensor according to a third embodiment of the present invention;

FIG. 5 is a sectional view showing an acceleration sensor according to a fourth embodiment of the present invention; and

FIG. 6 is a sectional view showing an acceleration sensor according to a fifth embodiment of the present invention.

### DESCRIPTION OF THE PREFERRED EMBODIMENTS

Preferred embodiments of the present invention will be hereinafter described with reference to the accompanying drawings.

### First Embodiment

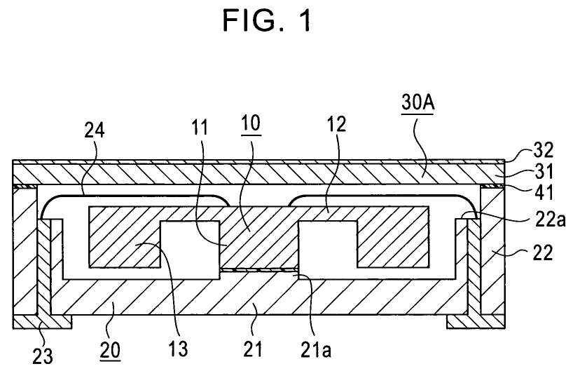

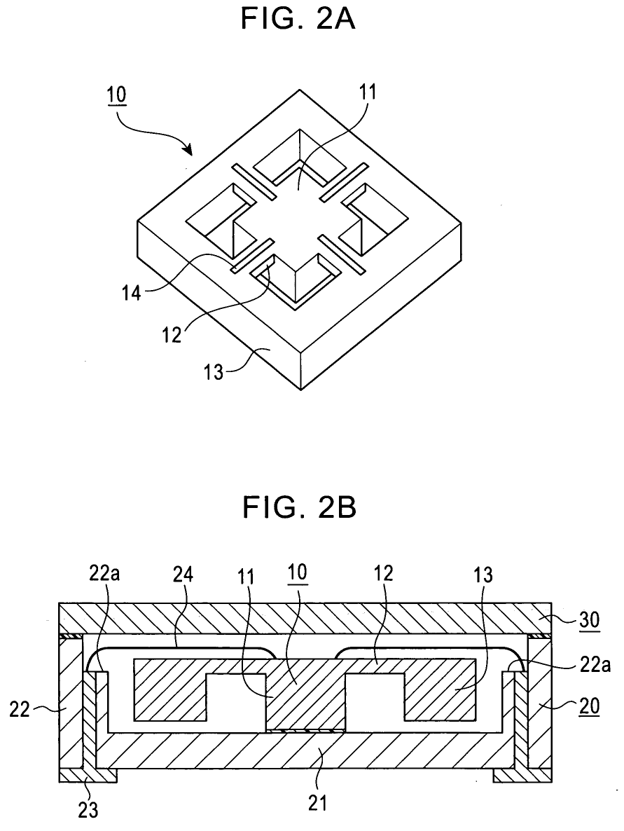

In FIG. 1, the same reference numerals are used for elements similar to those shown in FIGS. 2A and 2B.

As shown in FIG. 1, an acceleration sensor includes a sensor body 10 and a ceramic container 20 having the sensor body 10 received therein, which are similar to the sensor body 10 and the ceramic container 20 shown in FIGS. 2A and 2B. The acceleration sensor further includes a lid 30A for sealing a top part of the ceramic container 20, which is different from the lid 30 shown in FIGS. 2A and 2B.

Specifically, as shown in FIG. 2A, the sensor body 10, for example, includes a fixing part 11 for fixing the sensor body to the package, a weight part 13 supported by four beams 12 extending from the fixing part 11 so as to be displaced due to acceleration, and piezo resistance elements 14 respectively placed at the surfaces of the beams 12. The fixing part 11, the beams 12, and the weight part 13 are integrally shaped and made of silicon.

The ceramic container 20 includes a bottom part 21 and a sidewall part 22. A protrusion 21a is formed at the center of the bottom part 21, to which the fixing part 11 of the sensor body 10 is fixed by means of an adhesive agent. At the upper side of the sidewall part 22, a step part 22a is formed. A metal terminal 23 for an external connection penetrates through the sidewall part 22 so as to extend from the step part 22a to the outside of the bottom part 21. The piezo resistance elements 14 placed at the surface of the sensor body 10 is connected to the metal terminal 23 via metal wires 24.

On the other hand, the lid 30A is formed by applying a black color electrodeposition coating layer 32 on an outer surface of a 42 alloy plate 31, which is made of an alloy composed of 42% nickel and 58% iron. The electrodeposition coating layer 32 may be formed by plating the outer surface of the 42 alloy plate 31 with chrome, and then by forming a black color compound at the chrome plating layer. The thickness of the 42 alloy plate 31 is approximately 100 μm, and the thickness of the electrodeposition coating layer 32 is approximately 10 μm.

The lid 30A is fixed to the upper end of the sidewall part 22 of the ceramic container 20 by means of thermosetting resin 41 in a hermetically sealed fashion such that no outside moisture is introduced into the internal space of the ceramic container 20. The thickness of the thermosetting resin 41 after thermosetting is adjusted to be approximately 20 to 30 μm, and the difference in coefficient of thermal expansion between the lid 30A and the ceramic container 20 is absorbed by plastic deformation of the thermosetting resin 41. Noted that the weight part 13 of the sensor body 10 is spaced apart from the ceramic container 20 and the lid 30A such that the weight part 13 does not come into contact with the ceramic container 20 and the lid 30A even though the weight part 13 is displaced due to acceleration.

Operation of the acceleration sensor is similar to that shown in FIGS. 2A and 2B. Specifically, the acceleration sensor is mounted on an apparatus by means of the metal terminal 23 disposed at the rear side of the package. When acceleration is applied, the weight part 13 of the sensor body 10 is displaced, and then the four beams 12 are bent. As a result, resistance values of the piezo resistance elements 14 placed at the surfaces of the respective beams 12 are changed according to bending amounts of the beams 12. Accordingly, a three-dimensional direction and a magnitude of the acceleration are calculated based on the resistance values of the piezo resistance elements 14.

The acceleration sensor according to the first embodiment of the present invention therefore has the following advantages:

(a) The lid 30A with the black color electrodeposition coating layer 32 applied on the outer surface of the 42 alloy plate 31 is used for a lid of the package. Consequently, it is possible to reduce the thickness of the lid to approximately 0.1 mm, and thus, to reduce the thickness of the entire package to approximately 1 mm. Noted that the width and length of the package are both approximately 6.2 mm.

(b) Since the black color electrodeposition coating layer 32 is applied on the outer surface of the lid 30A, printing with a low-power laser beam is possible, and therefore, conventional manufacturing apparatuses can be used.

(c) Since the lid is made of a metal, the lid has excellent impact resistance.

(d) The material used for the lid 30A is less expensive than ceramic, and the material can be processed more easily than the ceramic. Consequently, a manufacturing cost can be reduced.

Furthermore, the black color electrodeposition coating layer 32 may be applied by means of a so-called alumite which is formed by oxidizing an aluminum plating. The alumite has excellent insulation properties, and therefore, electric short due to contact of the lid and the metal wires 24 can be prevented when the alumite is formed on an inner surface of the lid.

### Second Embodiment

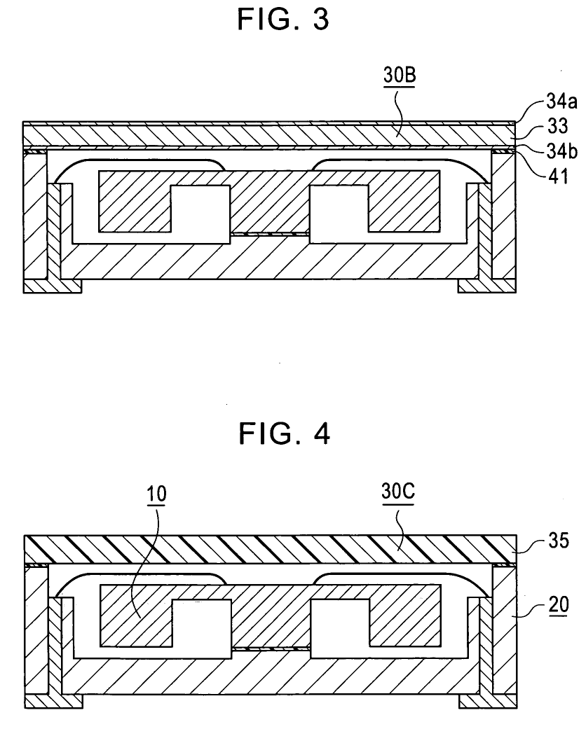

FIG. 3 is a sectional view showing an acceleration sensor according to a second embodiment of the present invention. In FIG. 3, the same reference numerals are used for elements similar to those used in FIG. 1.

The acceleration sensor includes a sensor body 10 and a ceramic container 20 having the sensor body 10 received therein, which are similar to the sensor body 10 and the ceramic container 20 shown in FIG. 1. The acceleration sensor further includes a lid 30B for sealing a top part of the ceramic container 20, which is different from the lid 30A shown in FIG. 1.

The lid 30B is formed by applying copper coating layers 34a and 34b each having a thickness of approximately 10 μm on opposite surfaces of a stainless steel 33 having a thickness of approximately 100 μm, respectively, and then by black-finishing the copper coating layers 34a and 34b by means of oxidization. The lid 30B is fixed to the upper end of the sidewall part 22 of the ceramic container 20 by means of thermosetting resin 41 having a thickness of approximately 20 to 30 μm, in a similar manner as the first embodiment of the present invention. Other construction and operation of the lid 30B are similar to those of the first embodiment.

The acceleration sensor according to the second embodiment of the present invention therefore has the following advantages:

(a) The lid 30B with the black-finished copper coating layers 34a and 34b applied on the opposite surfaces of the stainless steel 33 is used for a lid of the package. Consequently, it is possible to reduce the thickness of the lid to approximately 0.1 mm, and thus, to reduce the thickness of the entire package to approximately 1 mm.

(b) Since the surfaces of the lid 30B are black-finished, it is possible to imprint characters with a low-power laser beam, and therefore, conventional manufacturing apparatuses can be used.

(c) Since the lid is made of a metal, the lid has excellent impact resistance.

(d) The material used for the lid is less expensive than ceramic, and the material can be processed more easily than the ceramic. Consequently, a manufacturing cost can be reduced.

(e) The copper coating layers 34a and 34b, which are black-finished by oxidization, have excellent insulation properties, and therefore, no electric short occurs even though the lid 30B contacts with the metal wires 24.

### Third Embodiment

FIG. 4 is a sectional view showing an acceleration sensor according to a third embodiment of the present invention. In FIG. 4, the same reference numerals are used for elements similar to those used in FIG. 1.

The acceleration sensor includes a sensor body 10 and a ceramic container 20 having the sensor body 10 received therein, which are similar to the sensor body 10 and the ceramic container 20 shown in FIG. 1. The acceleration sensor further includes a lid 30C for sealing a top part of the ceramic container 20, which is different from the lid 30A shown in FIG. 1.

The lid 30C is made of a heat-resistant polyimide tape 35 having a thickness of approximately 100 μm. The lid 30C is fixed to the upper end of the sidewall part 22 of the ceramic container 20 by means of thermosetting resin 41 having a thickness of approximately 20 to 30 μm, in a similar manner as the first embodiment of the present invention. Other construction and operation of the lid 30C are similar to those of the first embodiment of the present invention.

The acceleration sensor according to the third embodiment of the present invention therefore has the following advantages:

(a) The heat-resistant polyimide tape 35 is used for a lid of the package. Consequently, it is possible to reduce the thickness of the lid to approximately 0.1 mm, and thus, to reduce the thickness of the entire package to approximately 1 mm.

(b) Since the lid 30C is made of the heat-resistant polyimide, it is possible to imprint characters with a low-power laser beam, and therefore, conventional manufacturing apparatuses can be used.

(c) The material used for the lid is less expensive than ceramic, and the material can be processed more easily than the ceramic. Consequently, a manufacturing cost can be reduced.

(d) The heat-resistant polyimide has an excellent insulation property, and therefore, no electric short occurs even though the lid 30C contacts with the metal wires 24.

It should be noted that a glass epoxy plate having a thickness of approximately 100 μm may be used instead of the heat-resistant polyimide tape 35. The lid made of glass epoxy plate provides similar advantage as the lid 30C made of the heat-resistant polyimide tape 35.

### Fourth Embodiment

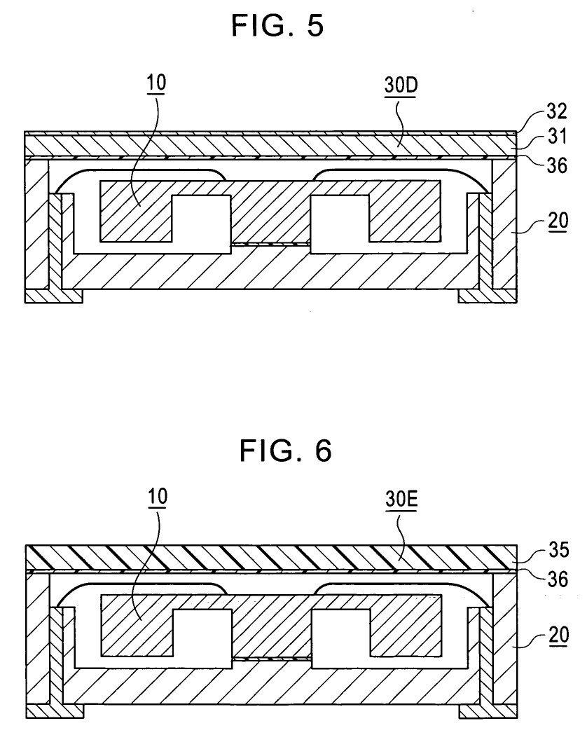

FIG. 5 is a sectional view showing an acceleration sensor according to a fourth embodiment of the present invention. In FIG. 5, the same reference numerals are used for elements similar to those used in FIG. 1.

The acceleration sensor includes a sensor body 10 and a ceramic container 20 having the sensor body 10 received therein, which are similar to the sensor body 10 and the ceramic container 20 shown in FIG. 1. The acceleration sensor further includes a lid 30D for sealing a top part of the ceramic container 20, which is slightly different from the lid 30A shown in FIG. 1.

The lid 30D is formed by applying a black color electrodeposition coating layer 32 on the outer surface of a 42 alloy plate 31 having a thickness of approximately 100 μm, in a similar manner as the first embodiment of the present invention, and by coating a thermoplastic resin 36 having a thickness of 20 to 30 μm on the entire surface of a back side, or an inner surface, of the 42 alloy plate 31. The lid 30D is fixed to the upper end of the sidewall part 22 of the ceramic container 20 by thermal pressing. Other construction and operation of the lid 30D are similar to those of the first embodiment of the present invention.

The acceleration sensor according to the fourth embodiment of the present invention therefore has the following advantages:

(a) The lid 30D with the black color electrodeposition coating layer 32 applied on the outer surface of the 42 alloy plate 31 is used for a lid of the package. Consequently, it is possible to reduce the thickness of the lid to approximately 0.1 mm.

(b) Since the black color electrodeposition coating layer 32 is applied on the outer surface of the lid 30D, it is possible to imprint characters with a low-power laser beam, and therefore, conventional manufacturing apparatuses can be used.

(c) Since the lid is made of a metal, the lid has excellent impact resistance.

(d) The material used for the lid is less expensive than ceramic, and the material can be processed more easily than the ceramic. Consequently, a manufacturing cost can be reduced.

(e) Since the thermoplastic resin 36 is coated on the entire surface of the inside of lid, no electric short occurs even though the lid 30D contacts with the metal wires 24.

(f) Since the coated thermoplastic resin 36 serves as an adhesive agent, application of the adhesive agent is not required when the ceramic container is covered with the lid.

It should be noted that a stainless steel 33 may be used instead of the 42 alloy plate 31 and a black-finished copper coating layer 34 may be used instead of the black color electrodeposition coating layer 32. This modification provides similar advantages as the fourth embodiment of the present invention.

### Fifth Embodiment

FIG. 6 is a sectional view showing an acceleration sensor according to a fifth embodiment of the present invention. In FIG. 6, the same reference numerals are used for elements similar to those used in FIG. 1.

The acceleration sensor includes a sensor body 10 and a ceramic container 20 having the sensor body 10 received therein, which are similar to the sensor body 10 and the ceramic container 20 shown in FIG. 1. The acceleration sensor further includes a lid 30E for covering the top part of the ceramic container 20, which is slightly different from the lid 30A shown in FIG. 1.

The lid 30E is formed by coating a thermoplastic resin 36 having a thickness of 20 to 30 μm on the entire surface of an inner side of a heat-resistant polyimide tape 35 having a thickness of approximately 100 μm. The lid 30E is fixed to the upper end of the sidewall part 22 of the ceramic container 20 by thermal pressing. Other construction and operation of the lid 30E are similar to those of the first embodiment of the present invention.

The acceleration sensor according to the fifth embodiment of the present invention therefore has the following advantages:

(a) The heat-resistant polyimide tape 35 is used for a lid of the package. Consequently, it is possible to reduce the thickness of the lid to approximately 0.1 mm, and thus, to reduce the thickness of the entire package to approximately 1 mm.

(b) Since the lid 30E is made of the heat-resistant polyimide, it is possible to imprint characters with a low-power laser beam, and therefore, conventional manufacturing apparatuses can be used.

(c) The materials used for the lid are less expensive than ceramic, and the materials can be processed more easily than the ceramic. Consequently, a manufacturing cost can be reduced.

(d) The heat-resistant polyimide and the thermoplastic resin have excellent insulation properties, and therefore, no electric short occurs even though the lid 30E contacts with the metal wires 24.

(e) Application of an adhesive agent is not required when the ceramic container is covered with the lid.

It should be noted that a glass epoxy plate having a thickness of approximately 100 μm may be used instead of the heat-resistant polyimide tape 35. The lid made of glass epoxy plate provides similar advantage as the lid 30E made of the heat-resistant polyimide tape 35.

This application is based on Japanese patent application No. 2004-371102 which is herein incorporated by reference.

What is claimed is:

1. A package for a semiconductor device comprising: a ceramic container having an internal space for receiving the semiconductor device; and a lid attached to an upper end of a sidewall part of the ceramic container for sealing the internal space of the ceramic container,
wherein the lid is formed by a black color electrodeposition coating layer applied either on the outer surface or the inner and outer surfaces of the a stainless steel plate or a 42 alloy plate.

2. A package for a semiconductor device comprising: a ceramic container having an internal space for receiving the semiconductor device; and a lid attached to an upper end of a sidewall part of the ceramic container for sealing the internal space of the ceramic container,
wherein the lid is formed by applying copper coating layers on the inner and outer surfaces of a stainless steel plate and by black-finishing the copper coating layers by means of oxidization.

3. A package for a semiconductor device comprising: a ceramic container having an internal space for receiving the semiconductor device; and a lid attached to an upper end of a sidewall part of the ceramic container for sealing the internal space of the ceramic container,
wherein the lid is formed by a heat-resistant polyimide tape or a glass epoxy plate.

4. The package according to claim 1, wherein a thermosetting resin is used to attach the lid to the ceramic container.

5. The package according to claim 1, wherein the lid is attached to the ceramic container by coating a thermoplastic resin on an entire surface of an inner side of the lid and by pressing the lid to the ceramic container while heating the thermoplastic resin.

6. The package according to claim 1, wherein the semiconductor device is an acceleration sensor integrally shaped and made of silicon, and the ceramic container has a protrusion at the bottom so as to attach a fixing part of the acceleration sensor.
